(19) United States
(12) Patent Application Publication
(10) Pub. No.: US 2026/0231755 A1
(43) Pub. Date: Aug. 6, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Jeong Gu Sim, Suwon-si (KR); Jin Woo Jeong, Suwon-si (KR)

(73) Assignee: Samsung Electronics Co., Ltd., Suwon-si (KR)

(21) Appl. No.: 19/329,749

(22) Filed: Sep. 16, 2025

(30) Foreign Application Priority Data
Feb. 4, 2025 (KR) 10-2025-0013797

(51) Int. Cl. H01L 23/528; H10D 62/10; H10D 64/23; H10D 84/83

(52) U.S. Cl. CPC H10W 20/435; H10D 64/2565; H10D 84/8312; H10D 84/832; H10W 20/43; H10D 62/121

(57) ABSTRACT

There is provided a semiconductor device having improved quality and performance. The semiconductor device comprising, a substrate, a first active pattern disposed on the substrate and extending in a first direction, a first gate structure disposed on the first active pattern and extending in a second direction intersecting the first direction, a second gate structure disposed on the first active pattern and spaced apart from the first gate structure in the first direction, wherein the second gate structure extends in the second direction, a first epitaxial pattern disposed between the first gate structure and the second gate structure and connected to the first active pattern, an insulating pattern covering at least a portion of an upper surface of the first epitaxial pattern, and a dummy contact disposed on an upper surface of the insulating pattern, wherein the dummy contact is spaced apart from the first epitaxial pattern via the insulating pattern.

### CROSS-REFERENCE TO RELATED APPLICATION

This present application claims priority to and the benefit under 35 U.S.C. § 119(a)-(d) of Korean Patent Application No. 10-2025-0013797, filed on Feb. 4, 2025, in the Korean Intellectual Property Office, the entire disclosure of which is incorporated herein by reference.

### FIELD

The present disclosure relates to a semiconductor device and a method for manufacturing the same. More specifically, the present disclosure relates to a semiconductor device including a source/drain contact, and a method for manufacturing the same.

### BACKGROUND

One of scaling schemes for increasing an integration density of an integrated circuit device includes a multi-gate transistor in which a fin-shaped or nanowire-shaped silicon body is formed on a substrate and a gate is formed on a surface of the silicon body.

Because such a multi-gate transistor uses a three-dimensional channel, it is easy to scale the same. Further, current control capability of the multi-gate transistor may be improved without increasing a gate length of the multi-gate transistor. In addition, the multi-gate transistor may effectively suppress SCE (short channel effect) in which potential of a channel area is affected by drain voltage.

### SUMMARY

Aspects of the present disclosure is to provide a semiconductor device having improved quality and performance.

Aspects of the present disclosure is to provide a method of manufacturing a semiconductor device having improved quality and performance.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to aspects of the present disclosure, there is provided a semiconductor device comprising, a substrate, a first active pattern disposed on the substrate and extending in a first direction, a first gate structure disposed on the first active pattern and extending in a second direction intersecting the first direction, a second gate structure disposed on the first active pattern and spaced apart from the first gate structure in the first direction, wherein the second gate structure extends in the second direction, a first epitaxial pattern disposed between the first gate structure and the second gate structure and connected to the first active pattern, an insulating pattern covering at least a portion of an upper surface of the first epitaxial pattern, and a dummy contact disposed on an upper surface of the insulating pattern, wherein the dummy contact is spaced apart from the first epitaxial pattern via the insulating pattern.

According to aspects of the present disclosure, there is provided a semiconductor device comprising, a substrate, an active pattern disposed on the substrate, a gate structure disposed on the substrate and intersecting the active pattern, a first epitaxial pattern disposed on one side surface of the gate structure and connected to the active pattern, an insulating pattern covering at least a portion of an upper surface of the first epitaxial pattern, an interlayer insulating film disposed on a side surface of the gate structure and covering the first epitaxial pattern and the insulating pattern, and a dummy contact disposed on an upper surface of the insulating pattern, wherein the dummy contact contacts the insulating pattern by penetrating the interlayer insulating film, wherein the insulating pattern and the interlayer insulating film include different insulating materials.

According to aspects of the present disclosure, there is provided a semiconductor device comprising, a substrate including a first surface and a second surface opposite to one another, an active pattern disposed on the first surface of the substrate and including a plurality of bridge patterns which are sequentially stacked and spaced apart from one another, a gate structure disposed on the active pattern, wherein the plurality of bridge patterns penetrate the gate structure, a first epitaxial pattern disposed on one side surface of the gate structure and connected to the plurality of bridge patterns, a second epitaxial pattern disposed on another side surface of the gate structure and connected to the plurality of bridge patterns, an insulating pattern covering at least a portion of an upper surface of the first epitaxial pattern, a dummy contact disposed on an upper surface of the insulating pattern and spaced apart from the first epitaxial pattern via the insulating pattern, a source/drain contact disposed on an upper surface of the second epitaxial pattern and connected to the second epitaxial pattern, a front wiring structure disposed on the dummy contact and the source/drain contact, wherein the front wiring structure is electrically connected to the source/drain contact, and a back wiring structure disposed on the second surface of the substrate.

According to aspects of the present disclosure, there is provided a method of manufacturing a semiconductor device comprising, forming a first active pattern extending in a first direction on a substrate, forming a first gate structure and a second gate structure on the active pattern, wherein the first gate structure and the second gate structure are spaced apart from one another in the first direction and each extending in a second direction intersecting the first direction, forming a first epitaxial pattern between the first gate structure and the second gate structure, wherein the first epitaxial pattern is connected to the first active pattern, forming an insulating pattern covering at least a portion of an upper surface of the first epitaxial pattern, and forming a dummy contact on an upper surface of the insulating pattern, wherein the dummy contact is spaced apart from the epitaxial pattern by the insulating pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is an example circuit diagram for illustrating a semiconductor device according to some embodiments.

FIG. 2 is an example layout diagram for illustrating a semiconductor device according to some embodiments.

FIG. 3 is a cross-sectional view taken along a line A-A of FIG. 2.

FIG. 4 is a cross-sectional view taken along a line B-B of FIG. 2.

FIG. 5 is a cross-sectional view taken along a line C-C of FIG. 2.

FIG. 6 is a cross-sectional view taken along a line D-D of FIG. 2.

FIGS. 7 to 10 are various example cross-sectional views for illustrating a semiconductor device according to some embodiments.

FIG. 11 is an example layout diagram for illustrating a semiconductor device according to some embodiments.

FIG. 12 is an example circuit diagram for illustrating a semiconductor device according to some embodiments.

FIG. 13 is an example layout diagram for illustrating a semiconductor device according to some embodiments.

FIG. 14 is a cross-sectional view taken along a line E-E of FIG. 13.

FIG. 15 is a cross-sectional view taken along a line F-F of FIG. 13.

FIG. 16 is an example layout diagram for illustrating a semiconductor device according to some embodiments.

FIGS. 17 to 28 are diagrams of intermediate structures corresponding to intermediate steps of a method for manufacturing a semiconductor device according to some embodiments.

FIGS. 29 and 30 are diagrams of intermediate structures corresponding to intermediate steps of a method for manufacturing a semiconductor device according to some embodiments.

### DETAILED DESCRIPTION

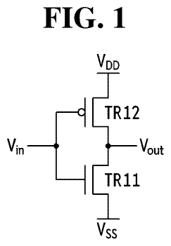

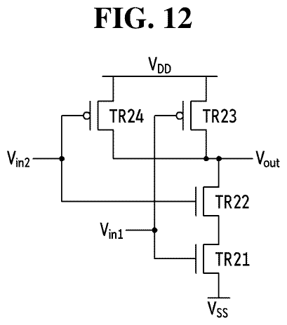

Hereinafter, a semiconductor device according to some embodiments will be described with reference to FIGS. 1 to 16. Embodiments disclosed with respect to FIGS. 1 to 11 mainly describe an inverter as a semiconductor device, and embodiments disclosed with reference to FIGS. 12 to 16 mainly describe a NAND gate as a semiconductor device. However, these are only examples. Those skilled in the art will understand that the technical idea of the present disclosure may be applied to various other logic devices such as a AND gate, a OR gate, a NOR gate, a XOR gate, etc., or various other semiconductor devices such as a static random access memory (SRAM) device.

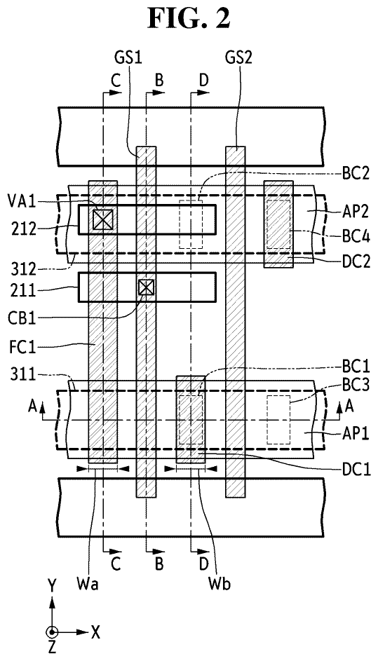

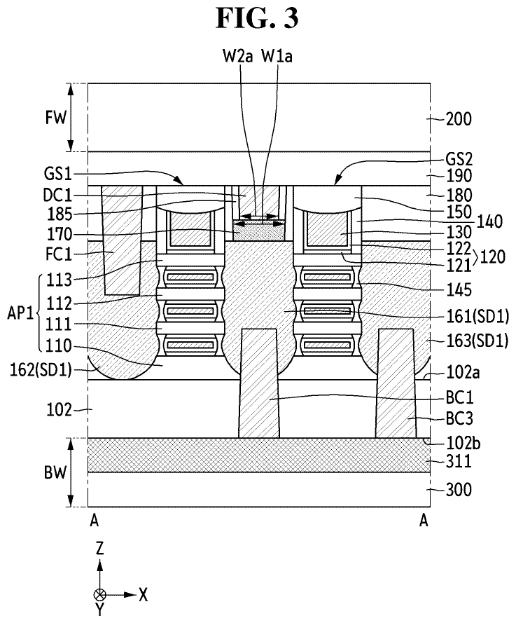

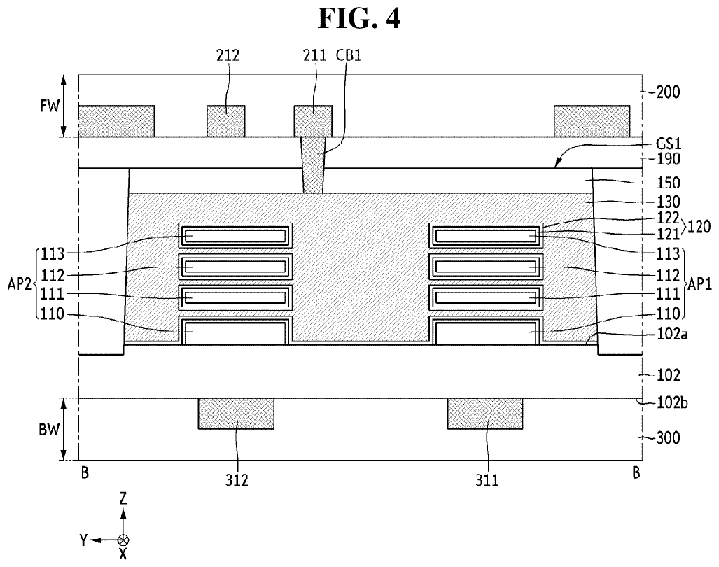

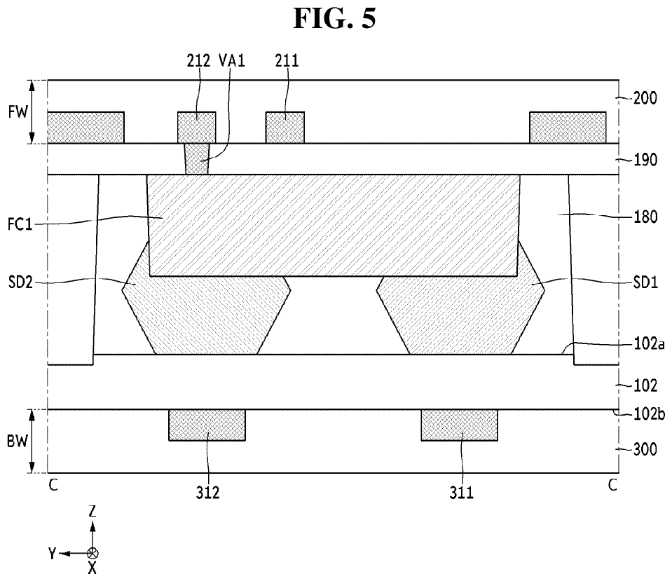

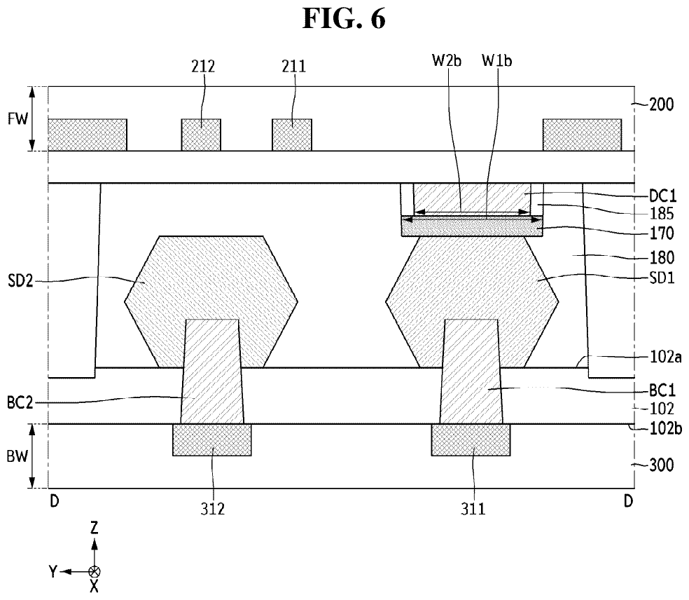

FIG. 1 is an example circuit diagram for illustrating a semiconductor device according to some embodiments. FIG. 2 is an example layout diagram for illustrating a semiconductor device according to some embodiments. FIG. 3 is a cross-sectional view taken along a line A-A of FIG. 2. FIG. 4 is a cross-sectional view taken along a line B-B of FIG. 2. FIG. 5 is a cross-sectional view taken along a line C-C of FIG. 2. FIG. 6 is a cross-sectional view taken along a line D-D of FIG. 2.

Referring to FIG. 1, the semiconductor device according to some embodiments may be provided as an inverter circuit.

For example, the semiconductor device according to some embodiments may include a first transistor TR11 and a second transistor TR12 disposed between and connected in series to a first power node V_{SS} and a second power node V_{DD}. The first transistor TR11 may be NFET, and the second transistor TR12 may be PFET. A source of the first transistor TR11 may be connected to the first power node V_{SS}, and a source of the second transistor TR12 may be connected to the second power node V_{DD}. An input signal Vᵢₙ of the inverter may be input to a gate of the first transistor TR11 and a gate of the second transistor TR12. An output signal Vₒᵤₜ of the inverter may be output from a node to which a drain of the first transistor TR11 and a drain of the second transistor TR12 are connected.

Referring to FIGS. 1 to 6, the semiconductor device according to some embodiments includes a substrate 102, first and second active patterns AP1 and AP2, first and second gate structures GS1 and GS2, first and second source/drain areas SD1 and SD2, a first interlayer insulating film 180, an insulating pattern 170, a second interlayer insulating film 185, a first source/drain contact FC1, first and second dummy contacts DC1 and DC2, a third interlayer insulating film 190, a front wiring structure FW, first to fourth back source/drain contacts BC1 to BC4, and a back wiring structure BW.

The substrate 102 may be made of bulk silicon or silicon-on-insulator (SOI). Alternatively, the substrate 102 may be a silicon substrate, or may include a material other than silicon, such as silicon germanium, silicon germanium on insulator (SGOI), indium antimonide, lead telluride compound, indium arsenide, indium phosphide, gallium arsenide, or gallium antimonide. Alternatively, the substrate 102 may include a base substrate and an epitaxial layer on the base substrate.

In some embodiments, the substrate 102 may be an insulating substrate including an insulating material. For example, the substrate 102 may include at least one of silicon oxide, silicon oxynitride, silicon oxycarbonitride, or a combination thereof. However, embodiments of the present disclosure are not limited thereto. For example, the substrate 102 may include a silicon oxide film.

The substrate 102 may include a first surface 102a and a second surface 102b opposite to one another. In following descriptions, the first surface 102a of the substrate 102 may also be referred to as a front surface or a front side of the substrate 102, and the second surface 102b of the substrate 102 may also be referred to as a back surface or a back side of the substrate 102.

The first and second active patterns AP1 and AP2 may be formed on the first surface 102a of the substrate 102. Each of the first and second active patterns AP1 and AP2 may extend in an elongate manner in a first direction X parallel to an upper surface of the substrate 102. The first and second active patterns AP1 and AP2 may be spaced apart from one another in a second direction Y parallel to the upper surface of the substrate 102 and intersecting the first direction X.

Each of the first and second active patterns AP1 and AP2 may include silicon (Si) or germanium (Ge) as an element semiconductor material. Alternatively, each of the first and second active patterns AP1 and AP2 may include a compound semiconductor, for example, a group IV-IV compound semiconductor or a group III-V compound semiconductor. The group IV-IV compound semiconductor may include, for example, a binary compound including two of carbon (C), silicon (Si), germanium (Ge), and tin (Sn), a ternary compound including three thereof, or a compound obtained by doping a group IV element thereto. The group III-V compound semiconductor may include, for example, a binary compound obtained by combining one of aluminum (Al), gallium (Ga), and indium (In) as a group III element and one of phosphorus (P), arsenic (As), and antimony (Sb) as a group V element with one another, a ternary compound obtained by combining two of aluminum (Al), gallium (Ga), and indium (In) as a group III element and one of phosphorus (P), arsenic (As), and antimony (Sb) as a group V with one another, or a quaternary compound obtained by combining three of aluminum (Al), gallium (Ga), and indium (In) as a group III element and one of phosphorus (P), arsenic (As), and antimony (Sb) as a group V with one another.

In some embodiments, the first and second active patterns AP1 and AP2 may be provided as channel areas of different conductivity types. In the following descriptions, an example in which the first active pattern AP1 is a channel area of the NFET and the second active pattern AP2 is a channel area of the PFET will be described. However, this is merely an example, and the first active pattern AP1 may be a channel area of the PFET, and the second active pattern AP2 may be a channel area of the NFET.

In some embodiments, each of the first and second active patterns AP1 and AP2 may include a plurality of bridge patterns 111 to 113. The plurality of bridge patterns 111 to 113 may be spaced apart from one another and sequentially stacked in a third direction Z intersecting the upper surface of the substrate 102 (e.g., the first surface 102a). The bridge patterns 111 to 113 may be used as a channel area of MBCFET® including the multi-bridge channel. The number of the bridge patterns 111 to 113 included in each of the first and second active patterns AP1 and AP2 is only an example, and is not limited to the illustrated example.

In some embodiments, each of the first and second active patterns AP1 and AP2 may further include a fin pattern 110 between the substrate 102 and the bridge patterns 111 to 113. The fin pattern 110 may protrude from the upper surface of the substrate 102 and extend in the first direction X. The bridge patterns 111 to 113 may be spaced apart from the fin pattern 110 in the third direction Z.

The first active pattern AP1 may be provided as a channel area of the first transistor TR11 of FIG. 1. The second active pattern AP2 may be provided as a channel area of the second transistor TR12 of FIG. 1.

Each of the first and second gate structures GS1 and GS2 may be formed on the first and second active patterns AP1 and AP2. Each of the first and second gate structures GS1 and GS2 may extend in the second direction Y. The first and second gate structures GS1 and GS2 may be spaced apart from one another in the first direction X. Each of the first and second gate structures GS1 and GS2 may intersect the first active pattern AP1 and the second active pattern AP2. For example, each of the bridge patterns 111 to 113 may extend in the first direction X so as to penetrate the first and second gate structures GS1 and GS2.

Each of the first and second gate structures GS1 and GS2 may include a gate dielectric film 120, a gate electrode 130, a gate spacer 140, and a gate capping film 150.

The gate dielectric film 120 may be interposed between each of the first and second active patterns AP1 and AP2 and the gate electrode 130. The gate dielectric film 120 may include a dielectric material, for example, at least one of silicon oxide, silicon oxynitride, silicon nitride, or a high dielectric constant material having a dielectric constant greater than that of silicon oxide. The high dielectric constant material may include at least one of for example, hafnium oxide (HfO2), zirconium oxide (ZrO2), lanthanum oxide (La2O3), aluminum oxide (Al2O3), titanium oxide (TiO2), strontium titanium oxide (SrTiO3), lanthanum aluminum oxide (LaAIO3), yttrium oxide (Y2O3), hafnium oxynitride (HfOxNy), zirconium oxynitride (ZrOxNy), lanthanum oxynitride (La2OxNy), aluminum oxynitride (Al2OxNy), titanium oxynitride (TiOxNy), strontium titanium oxynitride (SrTiOxNy), lanthanum aluminum oxynitride (LaAlOxNy), yttrium oxynitride (Y2OxNy) or combinations thereof. However, embodiments of the present disclosure are not limited thereto.

In some embodiments, the gate dielectric film 120 may include an interfacial film 121 and a high-k dielectric film 122 sequentially stacked on the first and second active patterns AP1 and AP2.

The interfacial film 121 may surround an outer periphery of each of the bridge patterns 111 to 113. For example, the interfacial film 121 may conformally extend along the outer periphery of each of the bridge patterns 111 to 113. The interfacial film 121 may extend along the surface of the fin pattern 110. In some embodiments, the interfacial film 121 may include an oxide film formed by oxidizing the surface of each of the respective bridge patterns 111 to 113 and/or the fin pattern 110. For example, when each of the bridge patterns 111 to 113 is a Si pattern, the interfacial film 121 may include a silicon oxide film.

The high-k dielectric film 122 may be formed on the interfacial film 121. The high-k dielectric film 122 may surround the interfacial film 121. In some embodiments, a portion of the high-k dielectric film 122 may be interposed between the gate electrode 130 and the gate spacer 140. For example, the high-k dielectric film 122 may conformally extend along a profile of a periphery of the interfacial film 121 and an inner side surface of the gate spacer 140. In addition, the high-k dielectric film 122 may further extend along the first surface 102a of the substrate 102. The high-k dielectric film 122 may include a high-k dielectric material having a dielectric constant greater than that of the silicon oxide.

The gate electrode 130 may extend in the second direction Y so as to intersect the first active pattern AP1 and the second active pattern AP2. Each of the bridge patterns 111 to 113 may extend in the second direction Y so as to penetrate the gate electrode 130. The gate electrode 130 may include a conductive material, for example, at least one of TiN, WN, TaN, Ru, TiC, TaC, Ti, Ag, Al, TiAl, TiAIN, TiAIC, TaCN, TaSiN, Mn, Zr, W, Al, and a combination thereof. However, embodiments of the present disclosure are not limited thereto. The gate electrode 130 may be formed in a replacement process. However, embodiments of the present disclosure are not limited thereto.

Although the gate electrode 130 is shown as being embodied as a single film, this is only an example, and the gate electrode 130 may be embodied as a multi-film structure formed by stacking a plurality of conductive films. For example, the gate electrode 130 may include a work function adjustment film for adjusting a work function, and a filling conductive film for filling a space defined by the work function adjustment film. The work function adjustment film may include, for example, at least one of TiN, TaN, TiC, TaC, TiAIC, and a combination thereof. The filling conductive film may include, for example, W or Al.

The gate spacer 140 may extend along a side surface of the gate electrode 130. Each of the bridge patterns 111 to 113 may extend in the second direction Y so as to penetrate the gate spacer 140. The gate spacer 140 may include an insulating material, for example, at least one of silicon oxide, silicon nitride, silicon oxynitride, silicon oxycarbide, silicon boron nitride, silicon boron carbonitride, silicon oxycarbonitride, and combinations thereof. However, embodiments of the present disclosure are not limited thereto.

The gate capping film 150 may extend along the upper surface of the gate electrode 130. The gate capping film 150 may include an insulating material, for example, at least one of silicon oxide, silicon nitride, silicon oxynitride, silicon oxycarbide, silicon boron nitride, silicon boron carbonitride, silicon oxycarbonitride, and combinations thereof. However, embodiments of the present disclosure are not limited thereto.

In some embodiments, each of the first and second gate structures GS1 and GS2 may further include an inner spacer 145. The inner spacer 145 may be formed on a side surface of a portion of the gate electrode 130 disposed between the bridge patterns 111 to 113. The inner spacer 145 may be formed on a side surface of a portion of the gate electrode 130 disposed between the fin pattern 110 and the bridge patterns 111 to 113. The inner spacer 145 may include an insulating material, for example, at least one of silicon oxide, silicon nitride, silicon oxynitride, silicon oxycarbide, silicon boron nitride, silicon boron carbonitride, silicon oxycarbonitride, and combinations thereof. However, embodiments of the present disclosure are not limited thereto.

The gate electrode 130 of the first gate structure GS1 may be provided as a gate of the first transistor TR11 of FIG. 1 and a gate of the second transistor TR12 of FIG. 1.

The first source/drain area SD1 may be formed on a side surface of the first active pattern AP1 and a side surface of each of the first and second gate structures GS1 and GS2. The bridge patterns 111 to 113 of the first active pattern AP1 may be connected to each of the first source/drain areas SD1 by penetrating the gate electrode 130 and the gate spacer 140. Each of the first source/drain areas SD1 may be isolated from the gate electrode 130 via the gate dielectric layer 120, the gate spacer 140, and/or the inner spacer 145.

The second source/drain area SD2 may be formed on a side surface of the second active pattern AP2 and on a side surface of each of the first and second gate structures GS1 and GS2. The bridge patterns 111 to 113 of the second active pattern AP2 may be connected each of the second source/drain areas SD2 by penetrating the gate electrode 130 and the gate spacer 140. Each of the second source/drain areas SD2 may be isolated from the gate electrode 130 via the gate dielectric layer 120, the gate spacer 140, and/or the inner spacer 145.

In some embodiments, each of the first and second source/drain areas SD1 and SD2 may include an epitaxial layer doped with impurities. For example, the first source/drain area SD1 may include an epitaxial pattern grown from the first active pattern AP1 using an epitaxial growth method. For example, the second source/drain area SD2 may include an epitaxial pattern grown from the second active pattern AP2 using an epitaxial growth method.

When the first active pattern AP1 acts as a channel area of NFET, the first source/drain area SD1 may include N-type impurities (e.g., P, Sb, or As) or impurities for preventing diffusion of N-type impurities.

When the second active pattern AP2 acts as a channel area of PFET, the second source/drain area SD2 may include P-type impurities (e.g., B, In, Ga, or Al) or impurities for preventing diffusion of P-type impurities.

The first interlayer insulating film 180 may be formed on the first and second gate structures GS1 and GS2 and the first and second source/drain areas SD1 and SD2. The first interlayer insulating film 180 may fill a space on an outer side surface of each of the first and second gate structures GS1 and GS2. The first interlayer insulating film 180 may cover the first and second source/drain areas SD1 and SD2.

The first interlayer insulating film 180 may include, for example, at least one of silicon oxide, silicon nitride, silicon oxynitride, silicon oxycarbide, silicon boron nitride, silicon boron carbide, silicon oxycarbonitride, and a low dielectric constant material having a dielectric constant lower than that of silicon oxide. However, embodiments of the present disclosure are not limited thereto. The low-k material may include, but is not limited to, at least one of FOX (Flowable Oxide), TOSZ (Tonene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and combinations thereof.

The insulating pattern 170 may be formed in the first interlayer insulating film 180. The insulating pattern 170 may be formed on the first source/drain area SD1 and/or the second source/drain area SD2. The insulating pattern 170 may cover at least a portion of an upper surface of the first source/drain area SD1 and/or at least a portion of an upper surface of the second source/drain area SD2. For example, as illustrated in FIG. 3, The first source/drain areas SD1 may include a first epitaxial pattern 161 between the first gate structure GS1 and the second gate structure GS2. The insulating pattern 170 may cover at least a portion of an upper surface of the first epitaxial pattern 161.

The insulating pattern 170 may include, for example, at least one of silicon oxide, silicon nitride, silicon oxynitride, silicon oxycarbide, silicon boron nitride, silicon boron carbonitride, silicon oxycarbonitride, and combinations thereof. However, embodiments of the present disclosure are not limited thereto. The insulating pattern 170 may include an insulating material different from that of the first interlayer insulating film 180. The first interlayer insulating film 180 and the insulating pattern 170 may have different etch selectivity. For example, when the first interlayer insulating film 180 includes a silicon oxide film, the insulating pattern 170 may include a silicon nitride film.

In some embodiments, a width of the insulating pattern 170 may decrease as the insulating pattern 170 extends toward the first surface 102a of the substrate 102. This may be due to characteristics of an etching process performed on the first interlayer insulating film 180 to form the insulating pattern 170.

In some embodiments, a vertical level of an upper surface of the insulating pattern 170 may be lower than a vertical level of the uppermost surface of the gate electrode 130. For example, based on the first surface 102a of the substrate 102, a vertical level of the upper surface of the insulating pattern 170 may be lower than a vertical level of the uppermost surface of the gate electrode 130. Accordingly, a vertical level of a bottom surface of a first dummy contact DC1 may be lower than the vertical level of the uppermost surface of the gate electrode 130.

The second interlayer insulating film 185 may be formed in the first interlayer insulating film 180. The second interlayer insulating film 185 may be formed on the insulating pattern 170. The second interlayer insulating film 185 may cover the upper surface of the insulating pattern 170. For example, the second interlayer insulating film 185 may fill a space on the upper surface of the insulating pattern 170.

The second interlayer insulating film 185 may include, for example, at least one of silicon oxide, silicon nitride, silicon oxynitride, silicon oxycarbide, silicon boron nitride, silicon boron carbide, silicon oxycarbonitride, and a low dielectric constant material having a dielectric constant lower than that of silicon oxide. However, embodiments of the present disclosure are not limited thereto. The second interlayer insulating film 185 may include an insulating material different from that of the insulating pattern 170. The insulating pattern 170 and the second interlayer insulating film 185 may have different etch selectivity. For example, when the insulating pattern 170 includes a silicon nitride film, the second interlayer insulating film 185 may include a silicon oxide film. The second interlayer insulating film 185 may include the same insulating material as that of the first interlayer insulating film 180, or may include an insulating material different from that of the first interlayer insulating film 180.

Although only a boundary between the first interlayer insulating film 180 and the second interlayer insulating film 185 is defined, this is only an example. In some cases, the boundary between the first interlayer insulating film 180 and the second interlayer insulating film 185 may not exist.

The first dummy contact DC1 may be interposed between the first gate structure GS1 and the second gate structure GS2. The first dummy contact DC1 may be formed on the insulating pattern 170. The insulating pattern 170 may be interposed between at least a portion of the first source/drain area SD1 and the first dummy contact DC1. For example, as illustrated in FIG. 3, the first dummy contact DC1 may be in contact with the upper surface of the insulating pattern 170 by penetrating the second interlayer insulating film 185. Accordingly, the first dummy contact DC1 may be spaced apart from the first epitaxial pattern 161 via the insulating pattern 170, and may be electrically isolated from the first epitaxial pattern 161.

In some embodiments, the first dummy contact DC1 may entirely overlap the insulating pattern 170 in the third direction Z. For example, as illustrated in FIG. 3, a width W1a in the first direction X of the insulating pattern 170 may be greater than or equal to a width W2a in the first direction X of the first dummy contact DC1. for another example, as illustrated in FIG. 6, a width W1b in the second direction Y of the insulating pattern 170 may be greater than or equal to a width W2b in the second direction Y of the first dummy contact DC1.

The first dummy contact DC1 may be disposed on a side surface of the second gate structure GS2, while a second dummy contact DC2 may be disposed on the other side surface of the second gate structure GS2. That is, the second gate structure GS2 may be interposed between the first dummy contact DC1 and the second dummy contact DC2. The second dummy contact DC2 may be formed on the insulating pattern 170. The insulating pattern 170 may be interposed between the second source/drain area SD2 and the second dummy contact DC2. The second dummy contact DC2 may be similar to the first dummy contact DC1 except that the second dummy contact DC2 is disposed on the second source/drain area SD2, and thus a detailed description thereof will be omitted.

The first source/drain contact FC1 may be disposed on a side surface of the first gate structure GS1, and the first dummy contact DC1 may be disposed on the other side surface of the first gate structure GS1. For example, the first gate structure GS1 may be interposed between the first source/drain contact FC1 and the first dummy contact DC1. The first source/drain contact FC1 may be formed on at least a portion of the first source/drain area SD1. The first source/drain contact FC1 may contact at least a portion of the first source/drain area SD1. For example, as illustrated in FIG. 3, the first source/drain areas SD1 may include a second epitaxial pattern 162 on a side surface of the first gate structure GS1. The first gate structure GS1 may intersect the first active pattern AP1 between the first epitaxial pattern 161 and the second epitaxial pattern 162. The first source/drain contact FC1 may be in contact with an upper surface of the second epitaxial pattern 162 by penetrating the first interlayer insulating film 180. Accordingly, the first source/drain contact FC1 may be electrically connected to the second epitaxial pattern 162.

The first source/drain contact FC1 may connect the first source/drain areas SD1 to the second source/drain areas SD2. For example, the first source/drain contact FC1 may extend in an elongate manner in the second direction Y so as to be in contact with both the first source/drain areas SD1 and the second source/drain areas SD2.

In some embodiments, as illustrated in FIG. 2, a width Wa in the first direction X of the first source/drain contact FC1 and a width Wb in the first direction X of the first dummy contact DC1 may be equal to one another.

In some embodiments, as illustrated in FIG. 3, an upper surface of the first source/drain contact FC1 and an upper surface of the first dummy contact DC1 may be coplanar with one another. Although it is illustrated that the upper surface of the first source/drain contact FC1 and the upper surface of the first dummy contact DC1 are coplanar with the upper surface of the first interlayer insulating film 180 and/or the upper surface of the gate capping film 150, this is only an example. In some embodiments, unlike the illustrated example, a vertical level of each of the upper surface of the first source/drain contact FC1 and the upper surface of the first dummy contact DC1 may be higher than a vertical level of each of the upper surface of the first interlayer insulating film 180 and/or the upper surface of the gate capping film 150.

Although each of the first dummy contact DC1, the second dummy contact DC2, and the first source/drain contact FC1 is illustrated as being embodied as a single film, this is only an example. For example, each of the first dummy contact DC1, the second dummy contact DC2, and the first source/drain contact FC1 may include a barrier conductive film and a filling conductive film filling a space defined by the barrier conductive film. The barrier conductive film may include a metal or a metal nitride for preventing diffusion of a metal element included in the filling conductive film. For example, the metal or the metal nitride may include at least one of titanium (Ti), tantalum (Ta), tungsten (W), nickel (Ni), cobalt (Co), platinum (Pt), an alloy thereof, and a nitride thereof. However, embodiments of the present disclosure are not limited thereto. The filling conductive film may include, for example, at least one of aluminum (Al), copper (Cu), tungsten (W), molybdenum (Mo), cobalt (Co), ruthenium (Ru) and alloys thereof. However, embodiments of the present disclosure are not limited thereto.

The first dummy contact DC1, the second dummy contact DC2, and the first source/drain contact FC1 may be formed at the same level. As used herein, “being formed at the same level” means being formed in the same manufacturing process. For example, the first dummy contact DC1, the second dummy contact DC2, and the first source/drain contact FC1 may have the same material composition.

The third interlayer insulating film 190 may be formed on the first interlayer insulating film 180, the second interlayer insulating film 185, the first dummy contact DC1, the second dummy contact DC2, and the first source/drain contact FC1. The third interlayer insulating film 190 may include, for example, at least one of silicon oxide, silicon nitride, silicon oxynitride, silicon oxycarbide, silicon boron nitride, silicon boron carbonitride, silicon oxycarbonitride, and a low dielectric constant material having a dielectric constant lower than that of silicon oxide. However, embodiments of the present disclosure are not limited thereto.

The front wiring structure FW may be formed on the third interlayer insulating film 190. The front wiring structure FW may include a front inter-wiring insulating film 200 and front wiring patterns 211 and 212 in the front inter-wiring insulating film 200. The shape, number, arrangement, and number of layers of the front inter-wiring insulating film 200 and the front wiring patterns 211 and 212 are only examples, and are not limited to those shown. Although not shown in detail, each of the front wiring patterns 211 and 212 may include a barrier conductive film and a filling conductive film.

In some embodiments, the front wiring patterns 211 and 212 may include a first front wiring pattern 211 and a second front wiring pattern 212 extending in the first direction X, respectively. The first front wiring pattern 211 and the second front wiring pattern 212 may be spaced apart from one another in the second direction Y.

The first front wiring pattern 211 may be connected to the first gate structure GS1. For example, as illustrated in FIG. 4, a first gate contact CB1 which contacts the gate electrode 130 of the first gate structure GS1 by penetrating the third interlayer insulating film 190 and the gate capping film 150 may be formed. The first front wiring pattern 211 may be electrically connected to the first gate structure GS1 via the first gate contact CB1.

The first front wiring pattern 211 may be connected to the input signal Vᵢₙ of the inverter IV. For example, an area of the first gate structure GS1 intersecting the first active pattern AP1 may be provided as a gate of the first transistor TR11 of FIG. 1, and an area of the first gate structure GS1 intersecting the second active pattern AP2 may be provided as a gate of the second transistor TR12 of FIG. 1.

The second front wiring pattern 212 may be connected to the first source/drain contact FC1. For example, as illustrated in FIG. 5, a first via pattern VA1 which connects the first source/drain contact FC1 and the second front wiring pattern 212 to one another by penetrating the third interlayer insulating film 190 may be formed. The second front wiring pattern 212 may be electrically connected to the first source/drain contact FC1 via the first via pattern VA1.

The second front wiring pattern 212 may be connected to the output signal Vₒᵤₜ of the inverter IV. For example, the first source/drain contact FC1 may be provided as a drain of the first transistor TR11 of FIG. 1 and a drain of the second transistor TR12 of FIG. 1.

In some embodiments, the front wiring structure FW may not be electrically connected to the first dummy contact DC1 and/or the second dummy contact DC2. For example, each of the first dummy contact DC1 and/or the second dummy contact DC2 may be electrically floating.

Each of first to fourth back source/drain contacts BC1 to BC4 may be formed under each of the first source/drain areas SD1 and/or the second source/drain areas SD2. Each of the first to fourth back source/drain contacts BC1 to BC4 may be connected to each of the first source/drain areas SD1 and/or the second source/drain areas SD2.

For example, as illustrated in FIG. 3, the first back source/drain contact BC1 may be in contact with a bottom surface of the first epitaxial pattern 161 by penetrating the substrate 102. Accordingly, the first back source/drain contact BC1 may be electrically connected to the first epitaxial pattern 161. In some embodiments, the first back source/drain contact BC1 may overlap the first dummy contact DC1 in the third direction Z.

For example, as illustrated in FIG. 3, the first source/drain areas SD1 may include a third epitaxial pattern 163 on the other side surface of the second gate structure GS2. The second gate structure GS2 may intersect the first active pattern AP1 between the first epitaxial pattern 161 and the third epitaxial pattern 163. The third back source/drain contact BC3 may be in contact with a bottom surface of the third epitaxial pattern 163 by penetrating the substrate 102. Accordingly, the third back source/drain contact BC3 may be electrically connected to the third epitaxial pattern 163.

Except for connected to the second source/drain areas SD2, the second back source/drain contact BC2 and the fourth back source/drain contact BC4 may be similar to the first back source/drain contact BC1 and the third back source/drain contact BC3, respectively, and thus detailed descriptions thereof will be omitted below.

The back wiring structure BW may be formed on the second surface 102b of the substrate 102. The back wiring structure BW may include a back inter-wiring insulating film 300 and back wiring patterns 311 and 312 in the back inter-wiring insulating film 300. The shape, number, arrangement, and number of layers of the back inter-wiring insulating film 300 and the back wiring patterns 311 and 312 are only examples, and are not limited to those shown. Although not shown in detail, each of the back wiring patterns 311 and 312 may include a barrier conductive film and a filling conductive film.

In some embodiments, the back wiring patterns 311 and 312 may include a first back wiring pattern 311 and a second back wiring pattern 312 extending in the first direction X, respectively. The first back wiring pattern 311 and the second back wiring pattern 312 may be spaced apart from one another in the second direction Y.

The first back wiring pattern 311 may be connected to the first source/drain areas SD1 via the first back source/drain contact BC1 and/or the third back source/drain contact BC3. For example, the first back wiring pattern 311 may be electrically connected to the first epitaxial pattern 161 via the first back source/drain contact BC1. For example, the first back wiring pattern 311 may be electrically connected to the third epitaxial pattern 163 via the third back source/drain contact BC3.

The first back wiring pattern 311 may be connected to the first power node V_{SS}. For example, the first back source/drain contact BC1 may be provided as a source of the first transistor TR11 of FIG. 1.

The second back wiring pattern 312 may be connected to the second source/drain areas SD2 via the second back source/drain contact BC2 and/or the fourth back source/drain contact BC4. The second back wiring pattern 312 may be similar to the first back wiring pattern 311 except that the second back wiring pattern 312 is connected to the second back source/drain contact BC2 and/or the fourth back source/drain contact BC4, and thus a detailed description thereof will be omitted below.

The second back wiring pattern 312 may be connected to the second power node V_{DD}. For example, the second back source/drain contact BC2 may be provided as a source of the second transistor TR12 of FIG. 1.

Depending on the design of the semiconductor device, a source/drain area not connected to the wiring structure may be provided. For example, as described above with reference to FIGS. 1 to 6, the first epitaxial pattern 161 interposed between the first gate structure GS1 and the second gate structure GS2 may act as a so-called shared source/drain, and may not be electrically connected to another node via the front wiring structure FW. Accordingly, the dummy source/drain contact contacting the shared source/drain may be at least partially omitted, which may contribute to reducing parasitic capacitance of the semiconductor device. However, indiscriminate omission of the dummy source/drain contact may cause a failure or a defect due to non-uniformity in the pattern density. In addition, such a defect or failure is getting more and more serious in a semiconductor device including a BSPDN (Back-Side Power Delivery Network) having a high omission percentage of the dummy source/drain contact.

Alternatively, the semiconductor device according to some embodiments may prevent the defect or failure due to the non-uniformity in the pattern density by using the insulating pattern 170. For example, as described above, although the first dummy contact DC1 is disposed on the first epitaxial pattern 161 provided as the shared source/drain, the first dummy contact DC1 may be spaced apart from the first epitaxial pattern 161 via the insulating pattern 170. Accordingly, the pattern density due to the first source/drain contact FC1 and the first dummy contact DC1 may be maintained, while increase in the parasitic capacitance due to the first dummy contact DC1 may be effectively prevented. Accordingly, the semiconductor device with improved quality and performance may be provided.

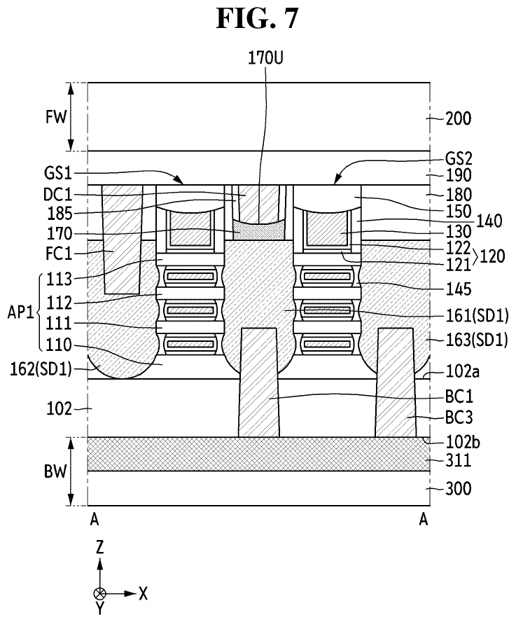

FIGS. 7 to 10 are various example cross-sectional views for illustrating a semiconductor device according to some embodiments. For convenience of description, a contents duplicate with those described above with reference to FIGS. 1 to 6 will be briefly described or the descriptions thereof will be omitted.

Referring to FIG. 7, in the semiconductor device according to some embodiments, the upper surface of the insulating pattern 170 includes a concave surface 170U that is concave upwardly.

The first dummy contact DC1 may be in contact with the concave surface 170U of the insulating pattern 170 by penetrating the second interlayer insulating film 185. In some embodiments, the second interlayer insulating film 185 may be in contact with the concave surface 170U of the insulating pattern 170. This may be due to the characteristics of a recess process for forming the insulating pattern 170.

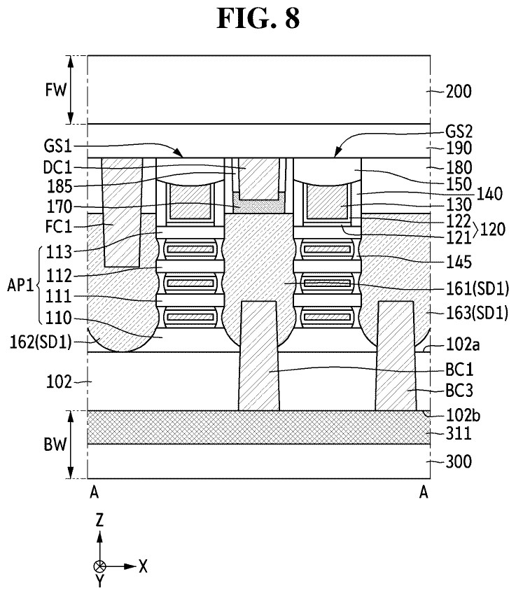

Referring to FIG. 8, in the semiconductor device according to some embodiments, a vertical level of the bottom surface of the first dummy contact DC1 is lower than a vertical level of the uppermost surface of the insulating pattern 170.

For example, based on the first surface 102a of the substrate 102, the vertical level of the bottom surface of the first dummy contact DC1 may be lower than the vertical level of the uppermost surface of the insulating pattern 170. for another example, a lower portion of the first dummy contact DC1 may be buried in the insulating pattern 170. This may be due to characteristics of an etching process performed on the insulating pattern 170 to form the first dummy contact DC1.

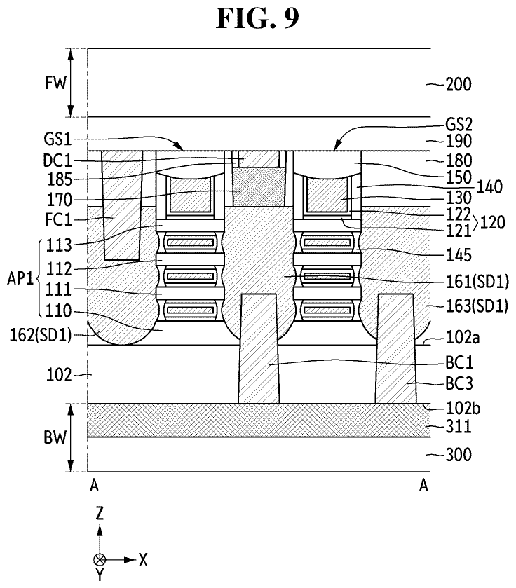

Referring to FIG. 9, in the semiconductor device according to some embodiments, a vertical level of the upper surface of the insulating pattern 170 is higher than a vertical level of the uppermost surface of the gate electrode 130.

For example, based on the first surface 102a of the substrate 102, the vertical level of the upper surface of the insulating pattern 170 may be higher than the vertical level of the uppermost surface of the gate electrode 130. Accordingly, a vertical level of a bottom surface of the first dummy contact DC1 may be higher than a vertical level of the uppermost surface of the gate electrode 130. In this case, a parasitic capacitance between the first dummy contact DC1 and the gate electrode 130 may be further reduced.

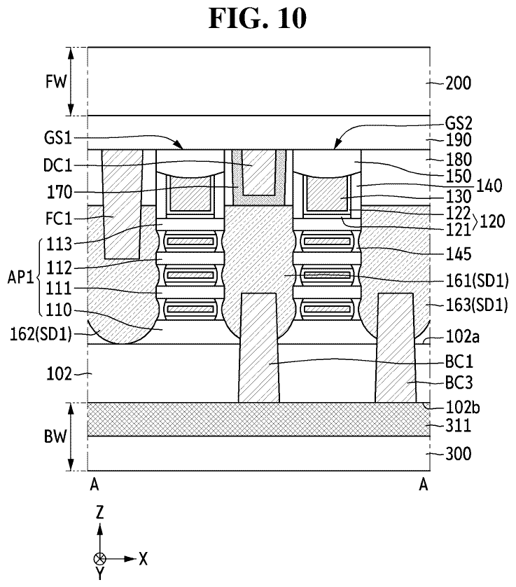

Referring to FIG. 10, in the semiconductor device according to some embodiments, a portion of the insulating pattern 170 is interposed between the first interlayer insulating film 180 and the first dummy contact DC1.

For example, the insulating pattern 170 may extend along and on the upper surface of the first epitaxial pattern 161 and the side surface of the first interlayer insulating film 180. In some embodiments, a side surface of the first dummy contact DC1 may be in contact with the insulating pattern 170. In some embodiments, unlike the illustrated example, the second interlayer insulating film 185 may be interposed between the side surface of the first dummy contact DC1 and the insulating pattern 170.

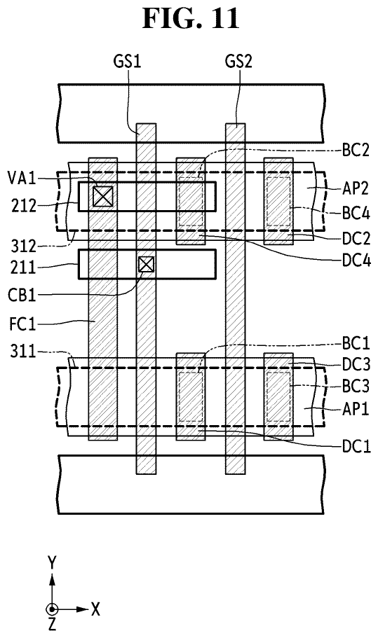

FIG. 11 is an example layout diagram for illustrating a semiconductor device according to some embodiments. For convenience of description, contents duplicate with those as described above with reference to FIGS. 1 to 10 will be briefly described or the descriptions thereof will be omitted.

Referring to FIG. 11, the semiconductor device according to some embodiments further includes a third dummy contact DC3 and a fourth dummy contact DC4.

The first dummy contact DC1 may be disposed on one side surface of the second gate structure GS2, and the third dummy contact DC3 may be disposed on the other side surface of the second gate structure GS2. The third dummy contact DC3 and the second dummy contact DC2 may be arranged in the second direction Y. The third dummy contact DC3 may be spaced apart from the first source/drain areas SD1 via the insulating pattern 170. In some embodiments, the third dummy contact DC 3 may overlap the third back source/drain contact BC3 in the third direction Z. Except for the position of the third dummy contact DC3, the third dummy contact DC3 may be similar to the first dummy contact DC1, and thus a detailed description thereof will be omitted below.

The fourth dummy contact DC4 may be disposed on one side surface of the second gate structure GS2, and the second dummy contact DC2 may be disposed on the other side surface of the second gate structure GS2. The first dummy contact DC1 and the fourth dummy contact DC4 may be arranged in the second direction Y. The fourth dummy contact DC4 may be spaced apart from the second source/drain areas SD2 via the insulating pattern 170. In some embodiments, the fourth dummy contact DC 4 may overlap the second back source/drain contact BC2 in the third direction Z. Except for a position of the fourth dummy contact DC4, the fourth dummy contact DC4 may be similar to the first dummy contact DC1, and thus a detailed description thereof will be omitted below.

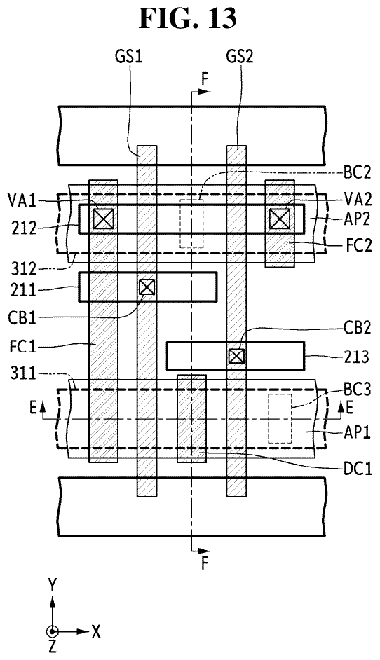

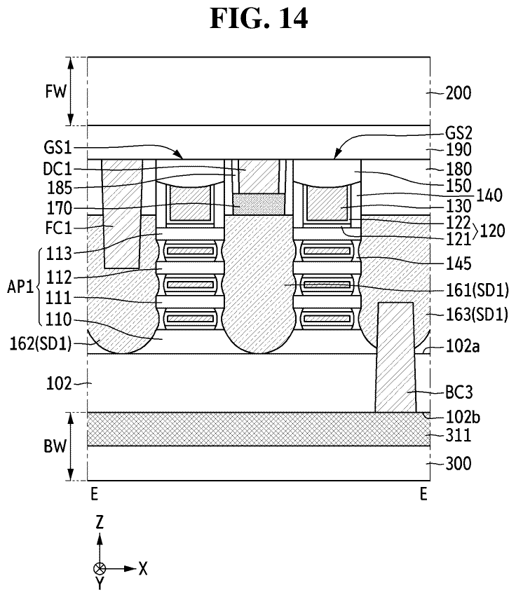

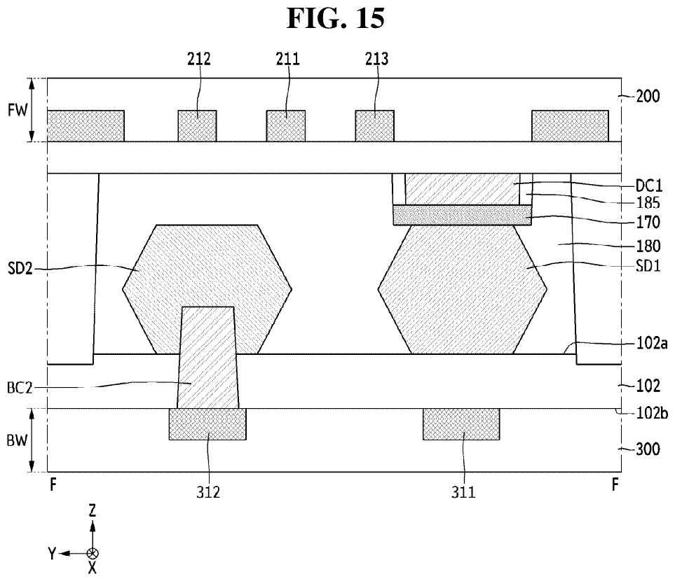

FIG. 12 is an example circuit diagram for illustrating a semiconductor device according to some embodiments. FIG. 13 is an example layout diagram for illustrating a semiconductor device according to some embodiments. FIG. 14 is a cross-sectional view taken along a line E-E of FIG. 13. FIG. 15 is a cross-sectional view taken along a line F-F of FIG. 13. For convenience of description, contents duplicate with those as described above with reference to FIGS. 1 to 11 will be briefly described or the descriptions thereof will be omitted.

Referring to FIG. 12, the semiconductor device according to some embodiments may be provided as an NAND gate circuit.

For example, the semiconductor device according to some embodiments may include a third transistor TR21, a fourth transistor TR22, a fifth transistor TR23, and a sixth transistor TR24 connected to and disposed between the first power node V_{SS} and the second power node V_{DD}. Each of the third transistor TR21 and the fourth transistor TR22 may be NFET, and each of the fifth transistor TR23 and the sixth transistor TR24 may be PFET. The third transistor TR21 and the fourth transistor TR22 may be connected in series to and disposed between the first power node V_{SS} and the output signal Vₒᵤₜ of the NAND gate. The fifth transistor TR23 and the sixth transistor TR24 may be connected in parallel with and disposed between the second power node V_{DD} and the output signal Vₒᵤₜ of the NAND gate.

A source of the third transistor TR21 may be connected to the first power node V_{SS}. A source of the fifth transistor TR23 and a source of the sixth transistor TR24 may be connected to the second power node V_{DD}. A first input signal Vᵢₙ₁ of the gate NAND may be input to the gate of the third transistor TR21 and the gate of the fifth transistor TR23. A second input signal Vᵢₙ₂ of the NAND gate may be input to the gate of the fourth transistor TR22 and the gate of the sixth transistor TR24. The output signal Vₒᵤₜ of the NAND gate may be output from a node to which a drain of the fourth transistor TR22, a drain of the fifth transistor TR23, and a drain of the sixth transistor TR24 are connected.

Referring to FIGS. 12 to 14, the semiconductor device according to some embodiments includes the substrate 102, the first and second active patterns AP1 and AP2, the first and second gate structures GS1 and GS2, the first and second source/drain areas SD1 and SD2, the first interlayer insulating film 180, the insulating pattern 170,the second interlayer insulating film 185, first and second source/drain contacts FC1 and FC2, the first dummy contact DC1, the third interlayer insulating film 190, the front wiring structure FW, the second and third back source/drain contacts BC2 and BC3, and the back wiring structure BW.

The first active pattern AP1 may be provided as a channel area of the third transistor TR21 of FIG. 12 and a channel area of the fourth transistor TR22 of FIG. 12. The second active pattern AP2 may be provided as a channel area of the fifth transistor TR 23 of FIG. 12 and a channel area of the sixth transistor TR 24 of FIG. 12.

The gate electrode 130 of the first gate structure GS1 may be provided as a gate of the fourth transistor TR22 of FIG. 12 and a gate of the sixth transistor TR24 of FIG. 12. The gate electrode 130 of the second gate structure GS2 may be provided as a gate of the third transistor TR21 of FIG. 12 and a gate of the fifth transistor TR23 of FIG. 12.

The first dummy contact DC1 may be disposed on one side surface of the second gate structure GS2, and the second source/drain contact FC2 may be disposed on the other side surface of the second gate structure GS2. That is, the second gate structure GS2 may be interposed between the first dummy contact DC1 and the second source/drain contact FC2. The second source/drain contact FC2 may be formed on the second source/drain areas SD2. The second source/drain contact FC2 may be connected the second source/drain areas SD2. The second source/drain contact FC2 may be similar to the first source/drain contact FC1 except that the second source/drain contact FC2 is connected to the second source/drain areas SD2, and thus a detailed description thereof will be omitted.

In some embodiments, the front wiring patterns 211, 212, and 213 may include the first front wiring pattern 211, the second front wiring pattern 212, and a third front wiring pattern 213, which extend in the first direction X, respectively. The first front wiring pattern 211, the second front wiring pattern 212, and the third front wiring pattern 213 may be spaced apart from one another in the second direction Y.

The third front wiring pattern 213 may be connected to the second gate structure GS2. For example, a second gate contact CB2 which contacts the gate electrode 130 of the second gate structure GS2 by penetrating the third interlayer insulating film 190 and the gate capping film 150 may be formed. The third front wiring pattern 213 may be electrically connected to the second gate structure GS2 via the second gate contact CB2.

The third front wiring pattern 213 may be connected to the first input signal Vᵢₙ₁ of the NAND gate. For example, an area of the second gate structure GS2 intersecting the first active pattern AP1 may be provided as a gate of the third transistor TR 21 of FIG. 12, and an area of the second gate structure GS2 intersecting the second active pattern AP2 may be provided as a gate of the fifth transistor TR 23 of FIG. 12.

The first front wiring pattern 211 may be connected to the first gate structure GS1. For example, the first gate contact CB1 which contacts the gate electrode 130 of the first gate structure GS1 by penetrating the third interlayer insulating film 190 and the gate capping film 150 may be formed. The first front wiring pattern 211 may be electrically connected to the first gate structure GS1 via the first gate contact CB1.

The first front wiring pattern 211 may be connected to the second input signal Vᵢₙ₂ of the NAND gate. For example, an area of the first gate structure GS1 intersecting the first active pattern AP1 may be provided as a gate of the fourth transistor TR 22 of FIG. 12, and an area of the first gate structure GS1 intersecting the second active pattern AP2 may be provided as a gate of the sixth transistor TR 24 of FIG. 12.

The second front wiring pattern 212 may be connected to the first source/drain contact FC1 and the second source/drain contact FC2. For example, the first via pattern VA1 which connects the first source/drain contact FC1 and the second front wiring pattern 212 to one another by penetrating the third interlayer insulating film 190 may be formed. In addition, for example, a second via pattern VA2 which connects the second source/drain contact FC2 and the second front wiring pattern 212 to one another by penetrating the third interlayer insulating film 190 may be formed. The second front wiring pattern 212 may electrically connect the first source/drain contact FC1 and the second source/drain contact FC2 via the first via pattern VA1 and the second via pattern VA2.

The second front wiring pattern 212 may be connected to the output signal Vₒᵤₜ of the NAND gate. For example, the first source/drain contact FC1 may be provided as a drain of the fourth transistor TR22 of FIG. 12 and a drain of the sixth transistor TR24 of FIG. 12. In addition, for example, the second source/drain contact FC2 may be provided as a drain of the fifth transistor TR 23 of FIG. 12.

The first back wiring pattern 311 may be connected to the first source/drain areas SD1 via a third back source/drain contact BC3. For example, the first back wiring pattern 311 may be electrically connected to the third epitaxial pattern 163 via the third back source/drain contact BC3.

The first back wiring pattern 311 may be connected to the first power node V_{SS}. For example, the third back source/drain contact BC3 may be provided as a source of the third transistor TR21 of FIG. 12.

The second back wiring pattern 312 may be connected to the second source/drain areas SD2 via the second back source/drain contact BC2. The second back wiring pattern 312 may be similar to the first back wiring pattern 311 except that the second back wiring pattern 312 is connected to the second back source/drain contact BC2, and thus a detailed description thereof will be omitted below.

The second back wiring pattern 312 may be connected to the second power node V_{DD}. For example, the second back source/drain contact BC2 may be provided as a source of the fifth transistor TR23 of FIG. 12 and a source of the sixth transistor TR24 of FIG. 12.

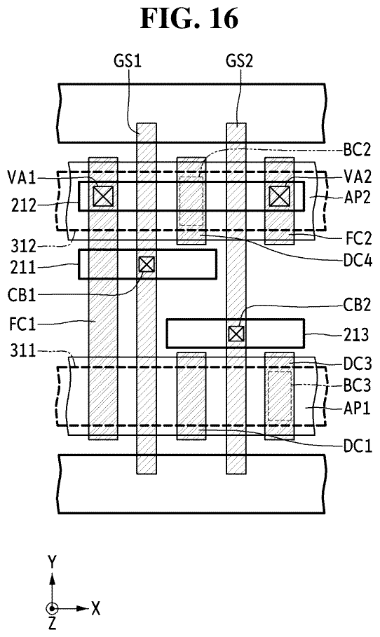

FIG. 16 is an example layout diagram for illustrating a semiconductor device according to some embodiments. For convenience of description, contents duplicate with those as described above with reference to FIGS. 1 to 15 will be briefly described or the descriptions thereof will be omitted.

Referring to FIG. 16, the semiconductor device according to some embodiments further includes the third dummy contact DC3 and the fourth dummy contact DC4.

The first dummy contact DC1 may be disposed on one side surface of the second gate structure GS2, and the third dummy contact DC3 may be disposed on the other side surface of the second gate structure GS2. The third dummy contact DC3 and the second source/drain contact FC2 may be arranged in the second direction Y. The third dummy contact DC3 may be spaced apart from the first source/drain areas SD1 via the insulating pattern 170. In some embodiments, the third dummy contact DC 3 may overlap the third back source/drain contact BC3 in the third direction Z. Except for the position of the third dummy contact DC3, the third dummy contact DC3 may be similar to the first dummy contact DC1, and thus a detailed description thereof will be omitted below.

The fourth dummy contact DC4 may be disposed on one side surface of the second gate structure GS2, while the second source/drain contact FC2 may be disposed on the other side surface of the second gate structure GS2. The first dummy contact DC1 and the fourth dummy contact DC4 may be arranged in the second direction Y. The fourth dummy contact DC4 may be spaced apart from the second source/drain areas SD2 via the insulating pattern 170. In some embodiments, the fourth dummy contact DC 4 may overlap the second back source/drain contact BC2 in the third direction Z. Except for a position of the fourth dummy contact DC4, the fourth dummy contact DC4 may be similar to the first dummy contact DC1, and thus a detailed description thereof will be omitted below.

Hereinafter, a method for manufacturing a semiconductor device according to example embodiments will be described with reference to FIGS. 1 to 30.

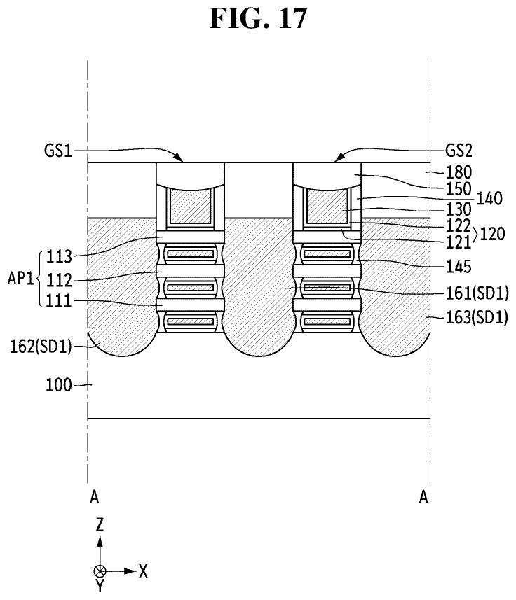

FIGS. 17 to 28 are diagrams of intermediate structures corresponding to intermediate steps of a method for manufacturing a semiconductor device according to some embodiments. For convenience of description, contents duplicate with those as described above with reference to FIGS. 1 to 16 will be briefly described or the descriptions thereof will be omitted.

Referring to FIG. 17, the first and second active patterns AP1 and AP2, the first and second gate structures GS1 and GS2, the first and second source/drain areas SD1 and SD2, and the first interlayer insulating film 180 may be formed on the base substrate 100. In following descriptions, the first active pattern AP1 and the first source/drain areas SD1 are mainly described. However, a person having ordinary skill in the art to which the present disclosure belongs will understand that the description may be equally applied to the second active pattern AP2 and the second source/drain areas SD2.

Each of the first and second active patterns AP1 and AP2 may extend in the first direction X. The first and second active patterns AP1 and AP2 may be spaced apart from one another in the second direction Y.

Each of the first and second gate structures GS1 and GS2 may extend in the second direction Y. The first and second gate structures GS1 and GS2 may be spaced apart from one another in the first direction X. Each of the first and second gate structures GS1 and GS2 may intersect the first active pattern AP1 and the second active pattern AP2.

The first source/drain area SD1 may be formed on the side surface of the first active pattern AP1 and on the side surface of each of the first and second gate structures GS1 and GS2. The second source/drain area SD2 may be formed on the side surface of the second active pattern AP2 and on the side surface of each of the first and second gate structures GS1 and GS2.

The first interlayer insulating film 180 may fill a space on the outer side surface of each of the first and second gate structures GS1 and GS2. The first interlayer insulating film 180 may cover the first and second source/drain areas SD1 and SD2.

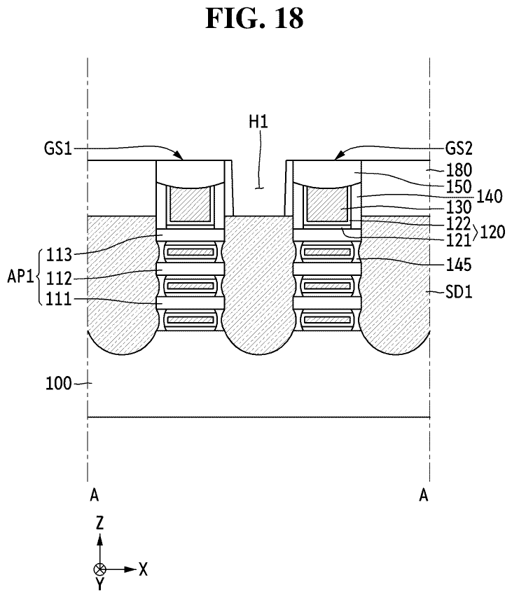

Referring to FIG. 18, a preliminary hole H1 is formed in the first interlayer insulating film 180.

The preliminary hole H1 may overlap at least a portion of the first source/drain area SD1 in the third direction Z. In some embodiments, the preliminary hole H1 may expose at least a portion of the upper surface of the first source/drain area SD1. In some embodiments, unlike the illustrated embodiment, the preliminary hole H1 may not expose the first source/drain area SD1.

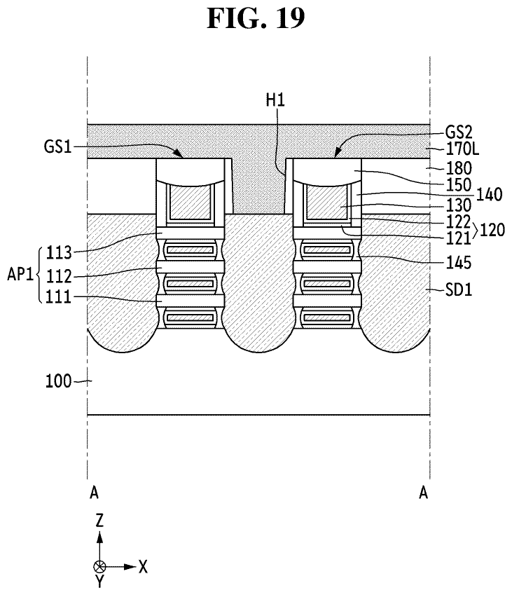

Referring to FIG. 19, a preliminary insulating film 170L is formed in the preliminary hole H1.

The preliminary insulating film 170L may fill at least a portion of the preliminary hole H1.

The preliminary insulating film 170L may include, for example, at least one of silicon oxide, silicon nitride, silicon oxynitride, silicon oxycarbide, silicon boron nitride, silicon boron carbonitride, silicon oxycarbonitride, and combinations thereof. However, embodiments of the present disclosure are not limited thereto. The preliminary insulating film 170L may include an insulating material different from that of the first interlayer insulating film 180. The first interlayer insulating film 180 and the preliminary insulating film 170L may have different etch selectivity from one another. For example, when the first interlayer insulating film 180 includes a silicon oxide film, the preliminary insulating film 170L may include a silicon nitride film.

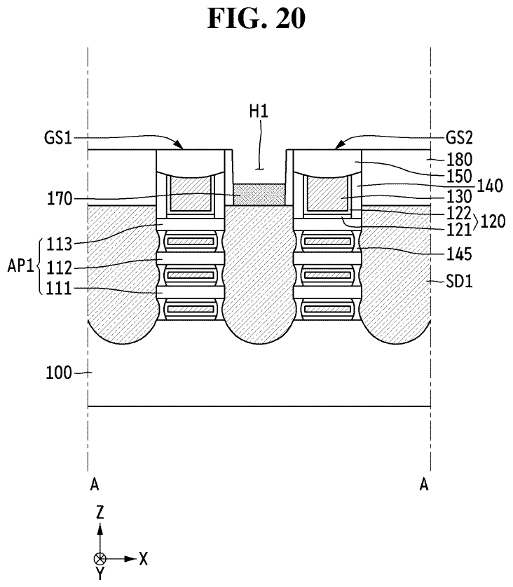

Referring to FIG. 20, a recess process may be performed on the preliminary insulating film 170L.

As the recess process is performed, the insulating pattern 170 may be formed to fill a portion of the preliminary hole H1. In some embodiments, a vertical level of the upper surface of the insulating pattern 170 may be lower than a vertical level of the uppermost surface of the gate electrode 130. In some embodiments, unlike the illustrated example, a vertical level of the upper surface of the insulating pattern 170 may be higher than a vertical level of the uppermost surface of the gate electrode 130.

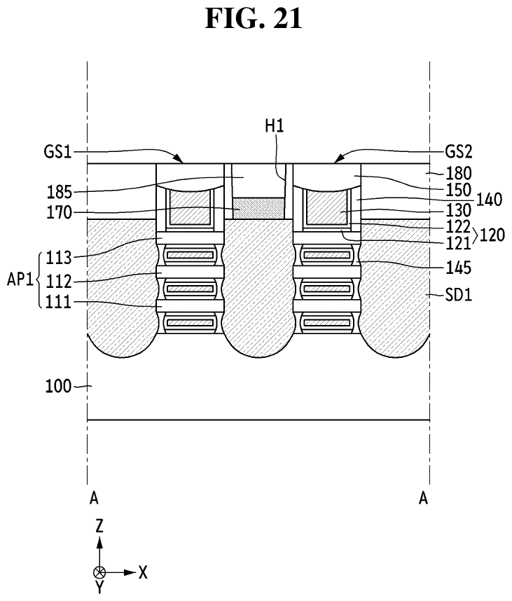

Referring to FIG. 21, the second interlayer insulating film 185 may be formed on the insulating pattern 170.

The second interlayer insulating film 185 may fill an area of the preliminary hole H1 remaining after the insulating pattern 170 has filled the hole H1. The second interlayer insulating film 185 may include the same insulating material as that of the first interlayer insulating film 180, or may include an insulating material different from that of the first interlayer insulating film 180.

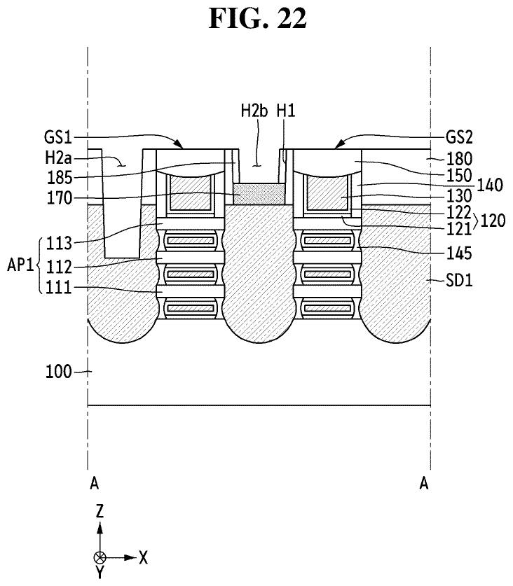

Referring to FIG. 22, a source/drain contact hole H2a and a dummy contact hole H2b are formed.

The source/drain contact hole H2a and the dummy contact hole H2b may be simultaneously formed in the same etching process. In the etching process, the insulating pattern 170 may serve as an etch stop film. Accordingly, the source/drain contact hole H2a may extend through the first interlayer insulating film 180 so as to expose at least a portion of the first source/drain areas SD1. In addition, the dummy contact hole H2b may extend through the second interlayer insulating film 185 so as to expose at least a portion of the upper surface of the insulating pattern 170.

In some embodiments, a width in the first direction X of the source/drain contact hole H2a and a width in the first direction X of the dummy contact hole H2b may be equal to one another.

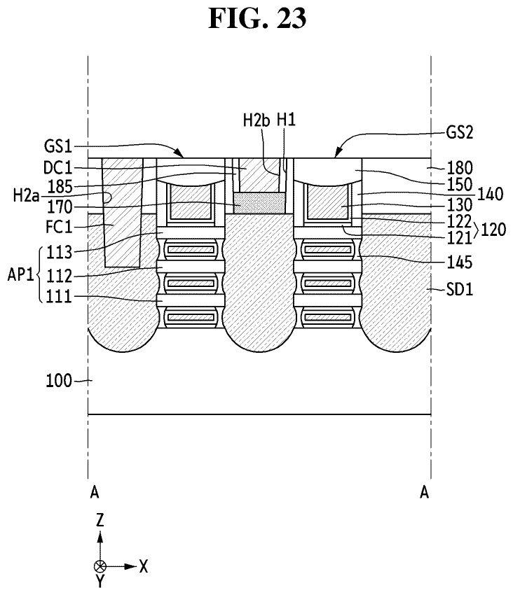

Referring to FIG. 23, the first source/drain contact FC1 and the first dummy contact DC1 may be formed.

The first source/drain contact FC1 may fill the source/drain contact hole H2a. As a result, the first source/drain contact FC1 may be formed to contact the first source/drain area SD1.

The first dummy contact DC1 may fill the dummy contact hole H2b. As a result, the first dummy contact DC1 may be formed to be spaced apart from the first source/drain areas SD1 via the insulating pattern 170.

The first source/drain contact FC1 and the first dummy contact DC1 may be simultaneously formed in the same deposition process. Accordingly, the first source/drain contact FC1 and the first dummy contact DC1 may have the same material composition.

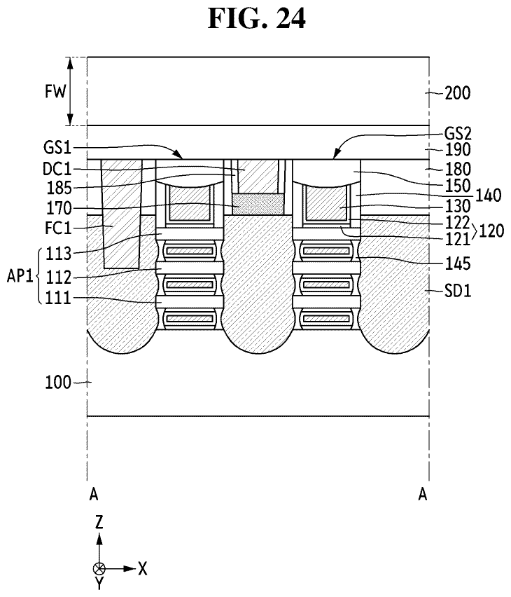

Referring to FIG. 24, the third interlayer insulating film 190 and the front wiring structure FW are formed.

The third interlayer insulating film 190 may cover the first interlayer insulating film 180, the second interlayer insulating film 185, the first source/drain contact FC1, and the first dummy contact DC1.

The front wiring structure FW may be formed on the third interlayer insulating film 190.

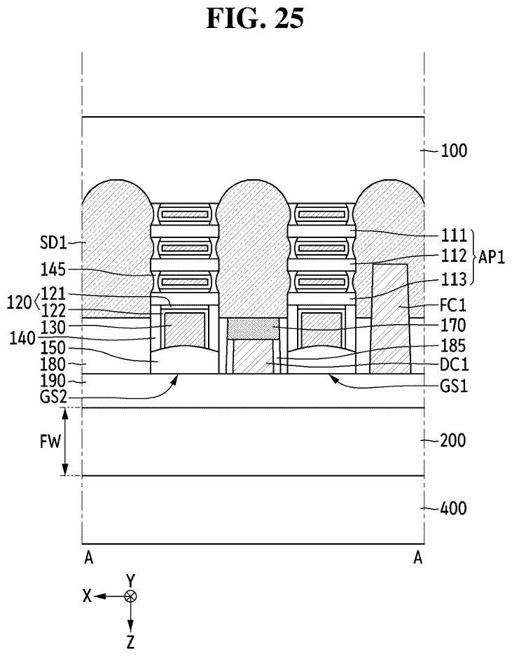

Referring to FIG. 25, the front wiring structure FW is attached onto a carrier substrate 400.

For example, the carrier substrate 400 may be attached onto the resultant structure of FIG. 24. After the carrier substrate 400 is attached thereto, the resultant structure of FIG. 24 may be turned upside down.

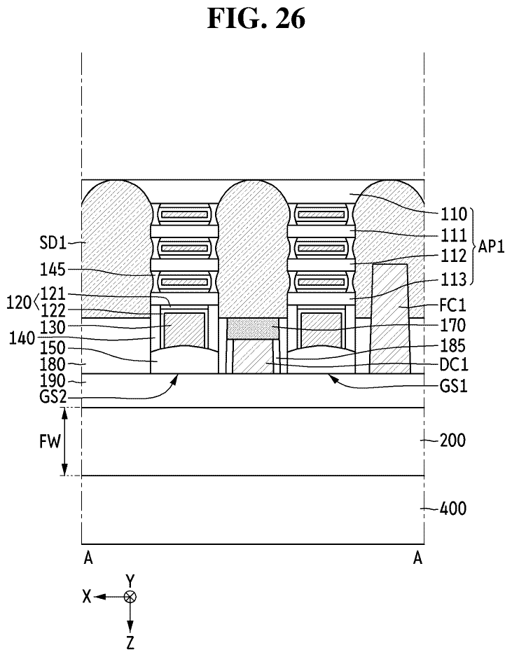

Referring to FIG. 26, a thinning process is performed on the base substrate 100

The thinning process may include, for example, a back grinding process on the back surface of the base substrate 100. However, embodiments of the present disclosure are not limited thereto.

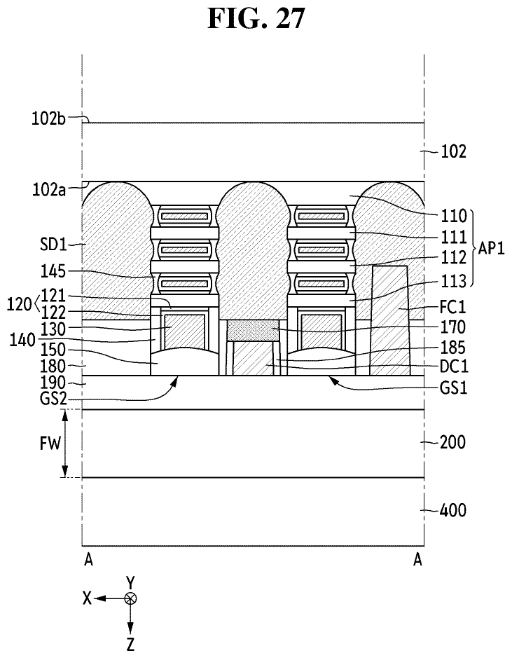

Referring to FIG. 27, the substrate 102 is formed.

For example, the substrate 102 including an insulating material replacing the area from which the base substrate 100 has been removed may be formed.

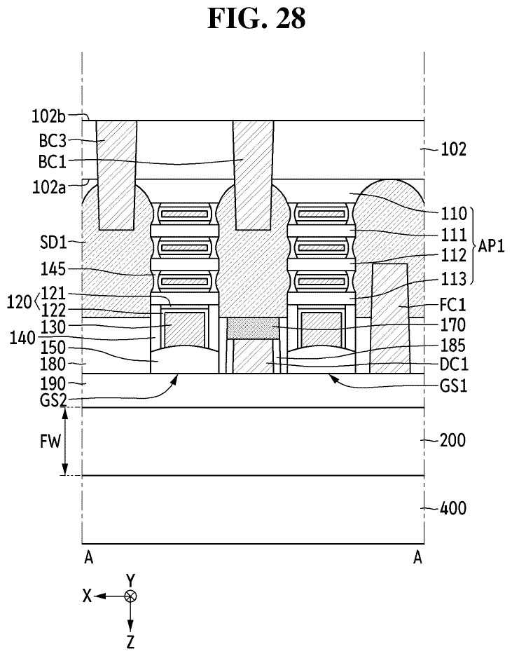

Referring to FIG. 28, the first to fourth back source/drain contacts BC1 to BC4 are formed.

Each of the first to fourth back source/drain contacts BC1 to BC4 may be connected to each of the first source/drain area SD1 and/or the second source/drain area SD2 by penetrating the substrate 102.

Subsequently, referring to FIG. 3, the back wiring structure BW is formed on the second surface 102b of the substrate 102. Thus, the semiconductor device as described above using FIGS. 1 to 6 may be manufactured.

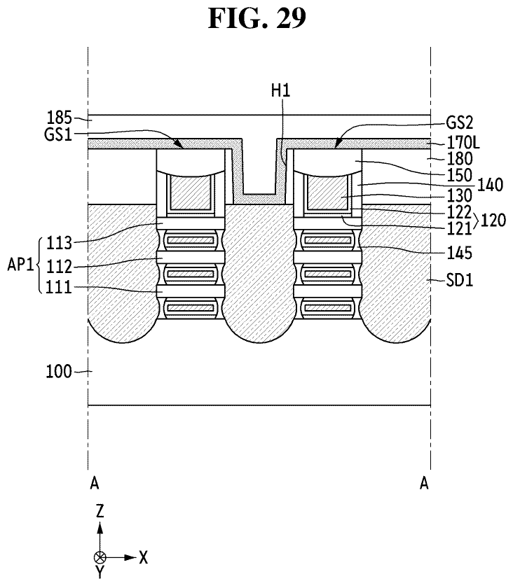

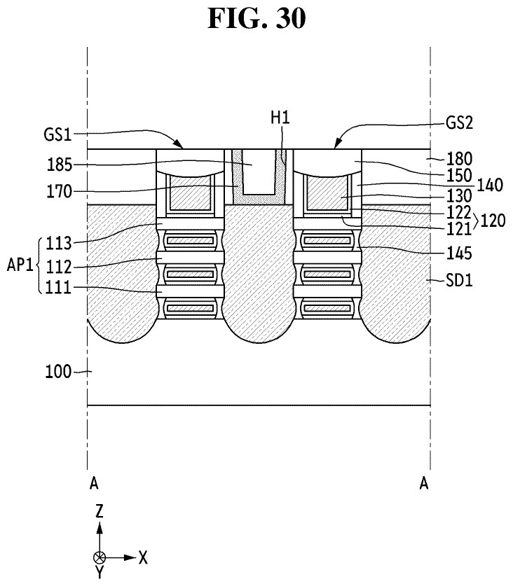

FIGS. 29 and 30 are diagrams of intermediate structures corresponding to intermediate steps of a method for manufacturing a semiconductor device according to some embodiments. For convenience of description, contents duplicate with those as described above using FIGS. 1 to 28 will be briefly described or the descriptions thereof will be omitted. For reference, FIG. 29 is a diagram of an intermediate structure corresponding to an intermediate step after FIG. 18.

Referring to FIG. 29, a preliminary insulating film 170L and the second interlayer insulating film 185 may be formed in the preliminary hole H1.

The preliminary insulating film 170L may conformally extend along a profile of the preliminary hole H1. The second interlayer insulating film 185 may be formed on the preliminary insulating film 170L. The second interlayer insulating film 185 may fill an area of the preliminary hole H1 remaining after the preliminary insulating film 170L has filled the hole H1.

Referring to FIG. 30, a planarization process may be performed on the preliminary insulating film 170L and the second interlayer insulating film 185.

The planarization process may include, for example, a Chemical Mechanical Polishing (CMP) process. However, embodiments of the present disclosure are not limited thereto. As the planarization process is performed, the insulating pattern 170 and the second interlayer insulating film 185 filling the preliminary hole H1 may be formed.

Subsequently, the steps as above-described using FIGS. 22 to 28 and 3 may be performed. Thus, the semiconductor device as described above using FIG. 10 may be manufactured.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor device comprising:
a substrate;
a first active pattern disposed on the substrate and extending in a first direction;
a first gate structure disposed on the first active pattern and extending in a second direction intersecting the first direction;
a second gate structure disposed on the first active pattern and spaced apart from the first gate structure in the first direction, wherein the second gate structure extends in the second direction;
a first epitaxial pattern disposed between the first gate structure and the second gate structure and connected to the first active pattern;
an insulating pattern covering at least a portion of an upper surface of the first epitaxial pattern; and
a dummy contact disposed on an upper surface of the insulating pattern, wherein the dummy contact is spaced apart from the first epitaxial pattern via the insulating pattern.

2. The semiconductor device of claim 1, wherein a width in the first direction of the insulating pattern is greater than or equal to a width in the first direction of the dummy contact.

3. The semiconductor device of claim 1, wherein a width in the second direction of the insulating pattern is greater than or equal to a width in the second direction of the dummy contact.

4. The semiconductor device of claim 1, further comprising a back source/drain contact disposed on a bottom surface of the first epitaxial pattern, wherein the back source/drain contact is connected to the first epitaxial pattern by penetrating the substrate.

5. The semiconductor device of claim 1, further comprising:
a second epitaxial pattern connected to the first active pattern, wherein the first gate structure is interposed between the first epitaxial pattern and the second epitaxial pattern; and
a source/drain contact disposed on an upper surface of the second epitaxial pattern, wherein the source/drain contact is connected to the second epitaxial pattern.

6. The semiconductor device of claim 5, wherein a width in the first direction of the dummy contact is substantially equal to a width in the first direction of the source/drain contact.

7. The semiconductor device of claim 5, wherein an upper surface of the dummy contact is coplanar with an upper surface of the source/drain contact.

8. The semiconductor device of claim 1, further comprising:
a second epitaxial pattern connected to the first active pattern, wherein the second gate structure is interposed between the first epitaxial pattern and the second epitaxial pattern; and
a back source/drain contact disposed on a bottom surface of the second epitaxial pattern, wherein the back source/drain is connected to the second epitaxial pattern by penetrating the substrate.

9. The semiconductor device of claim 1, further comprising an interlayer insulating film covering the upper surface of the insulating pattern,
wherein the dummy contact is in contact with the insulating pattern by penetrating the interlayer insulating film, and
wherein the insulating pattern and the interlayer insulating film include different insulating materials.

10. The semiconductor device of claim 9, wherein the insulating pattern includes a silicon nitride film,
wherein the interlayer insulating film includes a silicon oxide film.

11. The semiconductor device of claim 1, wherein the first active pattern includes a plurality of bridge patterns spaced apart from one another in a third direction intersecting an upper surface of the substrate.

12. A semiconductor device comprising:
a substrate;
an active pattern disposed on the substrate;
a gate structure disposed on the substrate and intersecting the active pattern;
a first epitaxial pattern disposed on one side surface of the gate structure and connected to the active pattern;
an insulating pattern covering at least a portion of an upper surface of the first epitaxial pattern;
an interlayer insulating film disposed on a side surface of the gate structure and covering the first epitaxial pattern and the insulating pattern; and
a dummy contact disposed on an upper surface of the insulating pattern,
wherein the dummy contact contacts the insulating pattern by penetrating the interlayer insulating film, and
wherein the insulating pattern and the interlayer insulating film include different insulating materials.

13. The semiconductor device of claim 12, wherein the insulating pattern includes a silicon nitride film,
wherein the interlayer insulating film includes a silicon oxide film.

14. The semiconductor device of claim 12, further comprising:
a second epitaxial pattern disposed on another side surface of the gate structure and connected to the active pattern; and
a source/drain contact disposed on an upper surface of the second epitaxial pattern and connect to the second epitaxial pattern.

15. The semiconductor device of claim 14, wherein the active pattern extends in a first direction,
wherein a width in the first direction of the dummy contact is substantially equal to a width in the first direction of the source/drain contact.

16. The semiconductor device of claim 14, wherein an upper surface of the dummy contact is coplanar with an upper surface of the source/drain contact.

17. The semiconductor device of claim 12, further comprising a back source/drain contact disposed on a bottom surface of the first epitaxial pattern, wherein the back source/drain contact is connected to the first epitaxial pattern by penetrating the substrate.

18. A semiconductor device comprising:
a substrate including a first surface and a second surface opposite to one another;
an active pattern disposed on the first surface of the substrate and including a plurality of bridge patterns which are sequentially stacked and spaced apart from one another;
a gate structure disposed on the active pattern, wherein the plurality of bridge patterns penetrate the gate structure;
a first epitaxial pattern disposed on one side surface of the gate structure and connected to the plurality of bridge patterns;
a second epitaxial pattern disposed on another side surface of the gate structure and connected to the plurality of bridge patterns;
an insulating pattern covering at least a portion of an upper surface of the first epitaxial pattern;
a dummy contact disposed on an upper surface of the insulating pattern and spaced apart from the first epitaxial pattern via the insulating pattern;
a source/drain contact disposed on an upper surface of the second epitaxial pattern and connected to the second epitaxial pattern;
a front wiring structure disposed on the dummy contact and the source/drain contact, wherein the front wiring structure is electrically connected to the source/drain contact; and
a back wiring structure disposed on the second surface of the substrate.

19. The semiconductor device of claim 18, wherein the front wiring structure is electrically disconnected from the dummy contact.

20. The semiconductor device of claim 18, further comprising a back source/drain contact electrically connecting the first epitaxial pattern to the back wiring structure by penetrating the substrate.
